(19) United States
(12) Patent Application Publication
(10) Pub. No.: US 2010/0044880 A1
(43) Pub. Date: Feb. 25, 2010

(54) SEMICONDUCTOR DEVICE AND SEMICONDUCTOR MODULE

(76) Inventors: Isamu AOKURA, Osaka (JP); Takashi YUI, Shiga (JP); Toshitaka AKAHOSHI, Shiga (JP)

Correspondence Address: MCDERMOTT WILL & EMERY LLP, 600 13TH STREET, NW, WASHINGTON, DC, 20005-3096, US

(21) Appl. No.: 12/428,273

(22) Filed: Apr. 22, 2009

(30) Foreign Application Priority Data
Aug. 19, 2008 (JP) 2008-210850

(51) Int. Cl. H01L 23/48

(52) U.S. Cl. 257/777; 257/778; 257/E23.01

(57) ABSTRACT

A semiconductor device includes a multilayer wiring substrate having a plurality of inner wiring layers and a semiconductor chip mounted on the multilayer wiring substrate. The multilayer wiring substrate has a groove formed in the bottom surface. The groove does not reach the lowermost of the inner wiring layers.

### CROSS-REFERENCE TO RELATED APPLICATION

This application claims priority from Japanese Patent Application No. JP2008-210850 filed on Aug. 19, 2008, which is hereby incorporated by reference in its entirety for all purposes.

### BACKGROUND

The present disclosure relates to a semiconductor device in which a semiconductor chip is mounted on a wiring substrate, and a semiconductor module.

With the growing demand for miniaturization and high performance of various electronic devices including mobile phones and digital cameras, smaller and thinner semiconductor devices are required. In recent years, since the area occupied on a circuit board could be largely reduced, attention has been particularly given to stacked semiconductor modules formed by stacking semiconductor devices one on another. In a stacked semiconductor module, semiconductor devices are subjected to burn-in tests before being mounted on a wiring substrate, and only the semiconductor devices identified as non-defective are used, so that the reliability as a module can be easily ensured. It is necessary to further reduce the thickness of a semiconductor device used in a stacked semiconductor module.

In mounting a semiconductor device on a mounting substrate such as a wiring substrate, there occurs warpage. When a semiconductor device and a mounting substrate are connected to each other, the semiconductor device and the mounting substrate are heated to form the connecting portion. When heated, the semiconductor device and the substrate exhibit different behaviors to increase the occurrence of warpage. When warpage occurs, the reliability of the connection between the semiconductor device and the mounting substrate will be reduced. Such warpage also occurs in manufacturing a stacked semiconductor module in which semiconductor devices are stacked one on another. In a stacked semiconductor module using low-profile semiconductor devices, the reduction in the reliability would be significant due to the increase in the amount of warpage.

In stacking semiconductor devices, in each of which a semiconductor chip is mounted on a wiring substrate, the following methods have been proposed to reduce effects of warpage. In a method, each of a first semiconductor device and a second semiconductor device is provided with a projecting electrode, and the projecting electrodes of the two semiconductor devices are connected to each other (see, for example, Japanese Published Patent Application H06-13541). By this configuration, even if warpage occurs in at least one of the wiring substrates of the first and second semiconductor devices, the projecting electrodes compensate effects of the warpage to improve the reliability of the connection.

In another method, grooves are formed in the both surfaces of a wiring substrate mounting a semiconductor chip so that the flexibility of the semiconductor device is improved to deal with the occurrence of warpage (see, for example, Japanese Published Patent Application H09-45809).

### SUMMARY

However, the present inventors have found that the above conventional semiconductor devices have the following problems.

First, when semiconductor devices are stacked one on another with projecting electrodes interposed therebetween, the projecting electrodes need to be formed outside the region on which a semiconductor chip is mounted. Thus, in a semiconductor device mounted with a large semiconductor chip or a plurality of semiconductor chips, the substrate mounting the semiconductor chip(s) is large in size. Since the projecting electrodes are formed in large regions, poor contact tends to easily occur at the connecting portion, when impact or thermal stress is applied externally. Furthermore, a solder ball bump is usually used for a projecting electrode. Due to the temperature at which the solder melts, the substrate mounting a semiconductor chip may deform to cause poor contact at the connecting portion.

On the other hand, in forming grooves on the both surfaces of a wiring substrate mounting a semiconductor chip, the grooves and the wiring region of the wiring substrate interfere with each other. This reduces the wiring capacity of the wiring substrate. In particular, multilayer wiring substrates, which have been used widely in recent years, wirings are arranged in a high density. Thus, when grooves are formed, wiring design in the wiring substrate is constrained. When this constraint is too limiting, wirings cannot be accommodated.

The present invention seeks to solve the problems mentioned above. In order to achieve a highly reliable semiconductor device, the present invention can be advantageous in reducing the occurrence of warpage, without reducing the wiring density of a wiring substrate mounting a semiconductor chip.

The present invention is directed to a semiconductor device including a groove in the bottom surface of a multilayer wiring substrate.

To be specific, a first example semiconductor device includes a multilayer wiring substrate having a plurality of inner wiring layers and a groove formed in the bottom surface of the multilayer wiring substrate, and a semiconductor chip mounted on the multilayer wiring substrate. The groove does not reach the lowermost of the inner wiring layers.

In the first example semiconductor device, the groove and the inner wiring layers do not interfere with each other. Thus, the wiring density of the multilayer wiring substrate does not decrease. Furthermore, since the groove is formed in the multilayer wiring substrate, the flexibility of the semiconductor device is improved to suppress the occurrence of warping. As a result, it is possible to achieve a semiconductor device having a reliable connection with a circuit board or the like, without reducing the wiring density.

A second example semiconductor device includes a multilayer wiring substrate having a plurality of inner wiring layers and a groove formed in the bottom surface of the multilayer wiring substrate, and a semiconductor chip mounted on the multilayer wiring substrate. The groove reaches a position higher than the lowermost of the inner wiring layers, and is formed except the inner wirings buried in the inner wiring layers.

In the second example semiconductor device, the groove and the inner wirings do not interfere with each other. Thus, the wiring density of the multilayer wiring substrate does not decrease. Since the groove can be formed deep, the occurrence of warping can be further suppressed. As a result, it is possible to achieve a semiconductor device having a reliable connection with a circuit board or the like, without reducing the wiring density.

A third example semiconductor device includes a multilayer wiring substrate, and a semiconductor chip mounted on the multilayer wiring substrate. The multilayer wiring substrate is a build-up substrate having two build-up layers and a core layer interposed between the build-up layers, and includes a groove formed from the bottom surface of the multilayer wiring substrate. The groove does not reach the build-up layer mounting the semiconductor chip.

As described above, in the third example semiconductor device, the groove does not reach the build-up layer mounting the semiconductor chip. In general, a lower build-up layer has a lower wiring density than an upper build-up layer. Thus, the groove does not affect the wiring density of the upper build-up layer having a higher wiring density. Since the groove is formed in the multilayer wiring substrate, the flexibility of the semiconductor device is improved to suppress the occurrence of warping. As a result, it is possible to achieve a semiconductor device having a reliable connection with a circuit board or the like, without reducing the wiring density.

### BRIEF DESCRIPTION OF THE DRAWINGS

FIGS. 1A and 1B illustrate an example semiconductor device. FIG. 1A is a plan view, and FIG. 1B is a cross-sectional view taken along the line Ib-Ib of FIG. 1A.

FIG. 2 is a plan view illustrating a modification of the example semiconductor device.

FIG. 3 is a cross-sectional view illustrating an example stacked semiconductor module.

FIG. 4 is a cross-sectional view illustrating a modification of the example semiconductor device.

FIG. 5 is a cross-sectional view illustrating a modification of the example semiconductor device.

### DETAILED DESCRIPTION

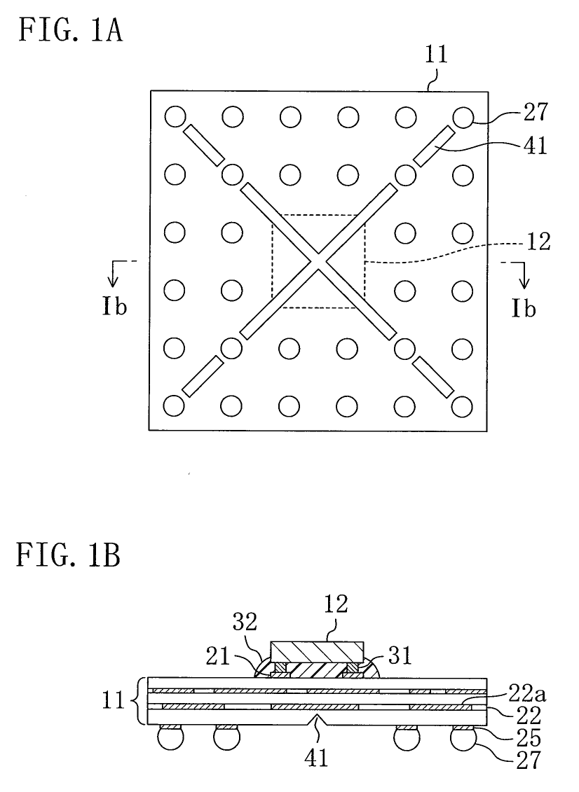

An embodiment of the present invention will be described with reference to the drawings. FIGS. 1A and 1B illustrate an example semiconductor device. FIG. 1A shows a planar configuration viewed from beneath, and FIG. 1B is a cross-sectional view taken along the line Ib-Ib of FIG. 1A.

As illustrated in FIG. 1, the example semiconductor device includes a semiconductor chip 12 mounted on a multilayer wiring substrate 11. The multilayer wiring substrate 11 includes a plurality of wirings formed in layers and on a surface of a substrate of a resin or the like. A resin is preferably used as the material of the multilayer wiring substrate 11 for cost reduction. For example, glass epoxy resin, polyimide resin, and aramid resin may be used. Alumina ceramic, aluminum nitride ceramic, glass, quartz and the like may be also used.

A chip mounting surface (the top surface) of the multilayer wiring substrate 11 is provided with an electrode 21 for connecting to the chip and a surface wiring (not shown) which is connected to the electrode 21 for connecting to the chip. Inner wiring layers 22 having inner wirings 22a are formed between layers in the multilayer wiring substrate 11. The opposite surface (the bottom surface) to the chip mounting surface of the multilayer wiring substrate 11 is provided with electrodes 25 for external connection. The electrodes 25 for external connection are electrically connected to the corresponding electrode 21 for connecting to the chip, with the inner wirings 22a and the surface wiring interposed therebetween. The surface of each electrode 25 for external connection is provided with a projecting electrode 27 for external connection to connect to a circuit board or the like.

In the bottom surface of the multilayer wiring substrate 11, groove portions 41 are formed. In the example semiconductor device, the groove portions 41 are formed shallower than the lowermost of the inner wiring layers 22. Since the groove portions 41 do not reach the lowermost of the inner wiring layers 22, the arrangement of the inner wirings 22a is not limited by the groove portions 41. Therefore, the wiring density of the multilayer wiring substrate 11 does not decrease.

In the example semiconductor device, two groove portions 41 are formed to coincide with diagonal lines of the multilayer wiring substrate 11. In this manner, when the multilayer wiring substrate 11 is provided with the groove portions 41 which cross each other and extend in a plurality of directions, the flexibilities of the multilayer wiring substrate 11 are improved uniformly in all directions. As a result, the reliability of the multilayer wiring substrate 11 is hardly lowered by warpage. Note that the groove portions 41 do not necessarily coincide with the diagonal lines.

In FIG. 1, the groove portions 41 are also formed in a region under the semiconductor chip 12. Under the semiconductor chip 12, there is often a region on which an electrode for external connection is not formed. The groove portions 41 are easily formed in such a region. Furthermore, the wiring density is often lower under the semiconductor chip 12 than at the outer edge of the wiring substrate. Thus, when a groove portion is formed in a region under the semiconductor chip, the wiring design at the outer edge of the wiring substrate can be easily implemented. Note that the groove portion is not necessarily formed in a region under the semiconductor chip.

The groove portions 41 are formed discontinuously not to overlap the electrodes 25 for external connection which are arranged in a grid array pattern. In this structure, the layout of the electrodes 25 for external connection is not limited. As long as the groove portions 41 do not overlap the electrodes 25 for external connection, the groove portions 41 may also be formed continuously. The groove portions 41 are easily formed in a linear shape, but may also be in a curved shape.

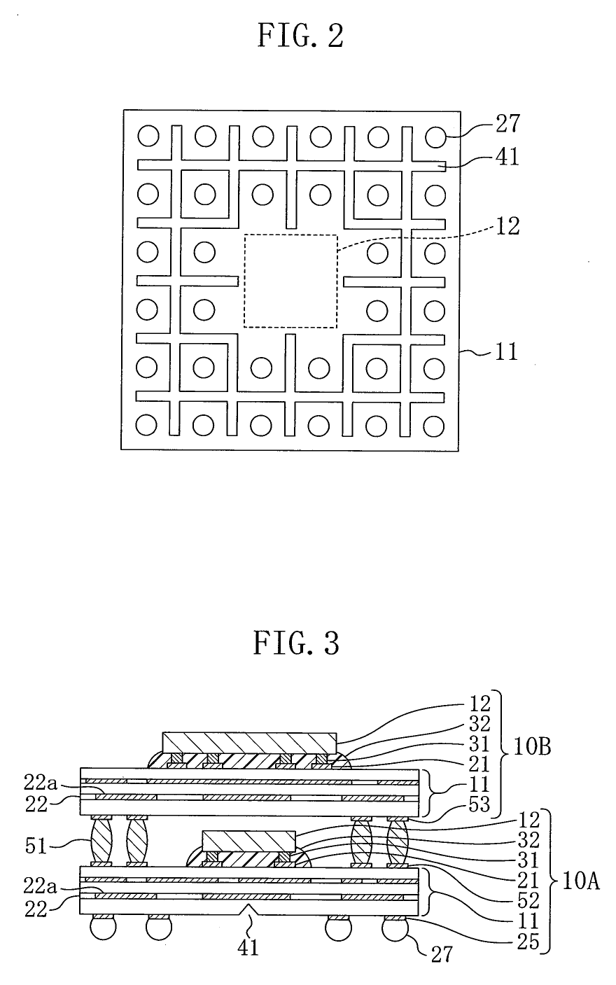

There is no limit to the number and the position of the groove portion(s), as long as the groove portion(s) 41 can prevent the occurrence of warpage in the multilayer wiring substrate 11. For example, as shown in FIG. 2, the groove portions 41 may be formed between the electrodes 25 for external connection in a lattice pattern. This structure significantly increases the flexibility of the multilayer wiring substrate 11. In this case, the groove portions 41 may not be formed under the region on which the semiconductor chip 12 is mounted. This does not reduce the strength of the region mounting the semiconductor chip 12. Note that a groove portion 41 may be formed under the region on which the semiconductor chip 12 is mounted.

The semiconductor chip 12 includes, for example, a circuit element formed on a silicon single crystal substrate. The thickness of the substrate can be reduced by polishing as appropriate. Note that, depending on the structure of the module, it is not necessarily polished. A substrate other than a silicon single crystal substrate, such as a compound semiconductor substrate or a Silicon on Insulator (SOI), may be used in the semiconductor chip.

The example semiconductor chip 12 includes a chip projecting electrode 31, and is flip chip bonded on the multilayer wiring substrate 11 so that the chip projecting electrode 31 is connected to the electrode 21 for connecting to the chip. The gap between the semiconductor chip 12 and the multilayer wiring substrate 11 is filled with a sealing resin 32. As a result, the semiconductor chip 12 is adhesively sealed to the multilayer wiring substrate 11. A non-conductive film (NCF), an anisotropic conductive film (ACF), and a liquid resin can be used as the sealing resin 32. In using a liquid resin, the chip projecting electrode 31 and the electrode 21 for connecting to the chip are connected to each other, and then the gap at the connecting portion can be filled with the liquid resin. In using an ACF, the ACF is attached to a chip mounting region, and then the semiconductor chip 12 is aligned to the region. The aligned portion is then pressured and heated. This allows the connection and adhesive sealing between the chip projecting electrode 31 and the electrode 21 for connecting to the chip, at the same time.

As an alternative to flip chip bonding, the semiconductor chip 12 may be mounted on the multilayer wiring substrate 11 by wire bonding or tape automated bonding (TAB).

The example semiconductor device may be a stacked module. For example, as shown in FIG. 3, a stacked module can be formed by stacking a semiconductor device 10A and a semiconductor device 10B with a connection terminal 51 interposed therebetween. In this case, when a groove portion 41 is formed in a multilayer wiring substrate 11 of the semiconductor device 10A, the flexibility of the stacked module is improved to increase the reliability of the connection between the stacked module and a circuit board. This also enhances the reliability of the connection between the semiconductor devices constituting the stacked module. The groove portion 41 may be formed in the multilayer wiring substrate 11 of the semiconductor device 10B instead of in the multilayer wiring substrate 11 of the semiconductor device 10A. The groove portion 41 may also be formed in each multilayer wiring substrate 11 of the semiconductor devices 10A and 10B.

In forming a stacked module, a connection electrode 52 can be formed on the top surface of the lower semiconductor device 10A, and a connection electrode 53 can be formed on the bottom surface of the upper semiconductor device 10B so that the connection electrode 52 and the connection electrode 53 are connected to each other by a connection terminal 51. The semiconductor devices may be stacked so that the semiconductor chips of the devices oppose each other. Three or more semiconductor devices may be stacked to form a semiconductor module.

The connection electrode 52, which is connected to the connection terminal 51, is formed on an outer edge of the multilayer wiring substrate 11 except the region on which the semiconductor chip 12 is mounted. In this case, the groove portion 41 is preferably formed inside the portion of the multilayer wiring substrate 11 which is connected to the connection terminal 51. This structure can avoid decrease in the strength of the portion connected to the connection terminal 51.

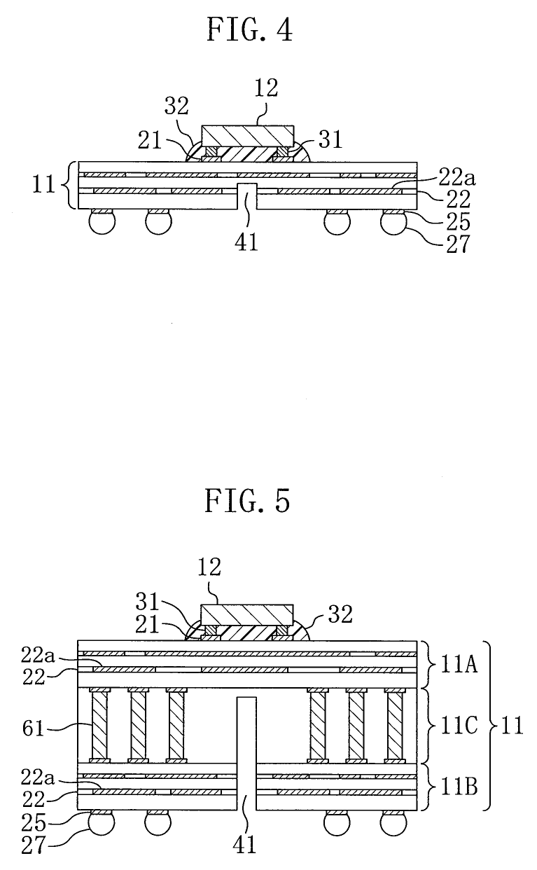

The example semiconductor device avoids the interference between the inner wirings 22a and the groove portion 41 by preventing the groove portion 41 from reaching the lowermost of the inner wiring layers 22. However, the multilayer wiring substrate 11 has a portion in which an inner wiring 22a is not formed. When the groove portion 41 is formed except the portion provided with the inner wirings 22a, the groove portion 41 may reach a portion deeper than the lowermost of the inner wiring layers 22, as shown in FIG. 4. By increasing the depth of the groove portion 41, the flexibility of the multilayer wiring substrate 11 is improved. This effectively suppresses warpage caused in connecting semiconductor devices, to secure a reliable connection.

As shown in FIG. 5, the multilayer wiring substrate 11 may be a build-up substrate, in which a core layer 11C is interposed between a build-up layer 11A and a build-up layer 11B. In FIG. 5, the upper build-up layer 11A and the lower build-up layer 11B include a plurality of inner wiring layers 22, and the core layer 11C includes a connection wiring 61 for connecting the upper build-up layer 11A and the lower build-up layer 11B.

In general, the lower build-up layer 11B has a lower wiring density than the upper build-up layer 11A. Thus, as shown in FIG. 5, even when a groove portion 41, which reaches the core layer 11C from the lower build-up layer 11B, is formed; the wiring capacity of the multilayer wiring substrate 11 as a whole does not decrease significantly. Note that the groove portion 41 does not necessarily reach the core layer 11C. For example, the above advantages can be obtained to some extent, even when the lower build-up layer 11B does not reach the lowermost of the inner wiring layers 22.

The example semiconductor chip 12 is shown in a square planar shape, but may be in other shapes such as a rectangular planar shape. The multilayer wiring substrate 11 is not necessarily in a square planar shape, but may be in other shapes such as a rectangular planar shape. A plurality of semiconductor chips 12 may be mounted on the multilayer wiring substrate 11. The electrodes 25 for external connection are arranged in a grid array pattern, but may be in other patterns. The term “grid array pattern” refers to a similar matrix arrangement to a Ball Grid Array (BGA) used for a surface mount type package.

As described above, the example semiconductor device and the semiconductor module can reduce the occurrence of warpage without reducing the wiring density of a wiring substrate mounting a semiconductor chip, and are therefore useful as a semiconductor device in which a semiconductor chip is mounted on a wiring substrate and a semiconductor module.

The description of the embodiments of the present invention is given above for the understanding of the present invention. It will be understood that the invention is not limited to the particular embodiments described herein, but is capable of various modifications, rearrangements and substitutions as will now become apparent to those skilled in the art without departing from the scope of the invention. Therefore, it is intended that the following claims cover all such modifications and changes as fall within the true spirit and scope of the invention.

What is claimed is:

1. A semiconductor device comprising:
a multilayer wiring substrate including a plurality of inner wiring layers and a groove formed in a bottom surface of the multilayer wiring substrate; and
a semiconductor chip mounted on the multilayer wiring substrate, wherein
the groove does not reach the lowermost of the inner wiring layers.

2. The device of claim 1, wherein
the number of the groove is two or more, and
the grooves are formed to extend linearly in different directions from each other.

3. The device of claim 2, wherein the grooves are formed discontinuously.

4. The device of claim 1, wherein
the semiconductor chip is mounted on a chip mounting region of the multilayer wiring substrate by flip-chip bonding, and
the groove is formed in a region including under the chip mounting region.

5. A semiconductor device comprising:
a multilayer wiring substrate including a plurality of inner wiring layers and a groove formed in a bottom surface of the multilayer wiring substrate; and
a semiconductor chip mounted on the multilayer wiring substrate, wherein
the groove reaches a position higher than the lowermost of the inner wiring layers, and is formed except inner wirings buried in the inner wiring layers.

6. The device of claim 5, wherein
the number of the groove is two or more, and
the grooves are formed to extend linearly in different directions from each other.

7. The device of claim 6, wherein the grooves are formed discontinuously.

8. The device of claim 5, wherein
the semiconductor chip is mounted on a chip mounting region of the multilayer wiring substrate by flip-chip bonding, and
the groove is formed in a region including under the chip mounting region.

9. A semiconductor device comprising:
a multilayer wiring substrate; and
a semiconductor chip mounted on the multilayer wiring substrate, wherein
the multilayer wiring substrate is a build-up substrate including two build-up layers and a core layer interposed between the build-up layers, and includes a groove formed from a bottom surface of the multilayer wiring substrate,
the groove does not reach the build-up layer mounting the semiconductor chip.

10. The device of claim 9, wherein
the multilayer wiring substrate includes a plurality of inner wiring layers, and
the groove does not reach the lowermost of the inner wiring layers.

11. The device of claim 9, wherein
the number of the groove is two or more, and
the grooves are formed to extend linearly in different directions from each other.

12. The device of claim 11, wherein the grooves are formed discontinuously.

13. The device of claim 9, wherein
the semiconductor chip is mounted on a chip mounting region of the multilayer wiring substrate by flip-chip bonding, and
the groove is formed in a region including under the chip mounting region.

14. A semiconductor module comprising a plurality of semiconductor devices stacked one on another, wherein
at least one of the plurality of semiconductor devices is the device of claim 1.

15. The module of claim 14, further comprising a connection terminal for connecting the semiconductor devices, wherein
the groove is formed inside a region of the multilayer wiring substrate connected to the connection terminal.
